(19) United States
(12) Patent Application Publication
(10) Pub. No.: US 2002/0124218 A1
(43) Pub. Date: Sep. 5, 2002

(54) Method of testing a semiconductor integrated circuit and method and apparatus for generating test patterns

(76) Inventor: Kazunori Kishimoto, Tokyo (JP)

Correspondence Address: KATTEN MUCHIN ZAVIS ROSENMAN, 575 MADISON AVENUE, NEW YORK, NY, 10022-2585, US

(21) Appl. No.: 10/083,447

(22) Filed: Feb. 26, 2002

(30) Foreign Application Priority Data
Mar. 1, 2001 (JP) 2001-057305

(51) Int. Cl. G01R 31/28; G06F 11/00

(52) U.S. Cl. 714/738; 714/726; 714/731; 714/728

(57) ABSTRACT

There is provided an apparatus and a method for automatically generating patterns including a pattern applied for a path that influences crosstalk to a measurement path, in a delay test using a scan path to make measurement of the effect of the path that influences crosstalk to the measurement path possible. An adjacent path extraction process 102 is performed on the basis of layout information on a semiconductor integrated circuit so as to extract information on a path that influences crosstalk, with reference to crosstalk information, a measurement path extraction process (106) is performed, so that information on an aggressor path that influences crosstalk to the measurement path of a combinational circuit between flip-flops that constitutes the scan path is generated, and then, on the basis of circuit information (108), and information (107) on the measurement path and the aggressor path, a Delay_test ATG (109) generates delay test patterns (110), including a pattern for outputting a signal for measuring a delay from a flip-flop associated with the measurement path and a pattern for outputting a signal that influence crosstalk to the measurement path from a flip-flop associated with the aggressor path.

### FIELD OF THE INVENTION

This invention relates to a device test technique of a semiconductor integrated circuit. More specifically, this invention relates to a method of testing a semiconductor integrated circuit, and a method, an apparatus, and a computer program product for automatically generating patterns for testing a semiconductor integrated circuit, preferably adapted for an AC test using a scan path.

### BACKGROUND OF THE INVENTION

As one of DFT (Design For Testability) approaches for designing a semiconductor integrated circuit device, a scan path design has been employed. In this technique, a plurality of flip-flops arranged in a logic circuit are connected in series in a scan mode to compose a shift register (termed a scan register). Each of flip-flops forming a scan path, based on an input scan clock, latches and delivers a signal which is entered from scan-in terminal as an initialization pattern to a flip-flop arranged in a subsequent stage for initialization, and the status information of a scan register, that is, the status monitoring pattern, is serially outputted from a scan-out terminal.

In the semiconductor integrated circuit device designed based on a scan path technique, a combinational circuit (combinational logic) connected between the scan registers receives parallel outputs from the scan register disposed on the input side of the combinational circuit and outputs the results of an logic operation to the scan register disposed on the output side of the combination circuit. The scan register on the output side of the combinational circuit samples synchronized with an input clock the result of the logic operation performed by the combinational circuit.

An example of the conventional technique of an AC (alternating current) test that utilizes the scan path will be described below. As a system of checking a delay fault in a semiconductor integrated circuit that adopts a scan path design, a reference may be made to a publication such as Japanese Patent Registration No.3090929. In the method proposed by the Japanese Patent Registration No.3090929, input patterns I for sensitizing (activating) a specific test path in a combinational circuit is determined.

Then, an input pattern II for loading the input pattern I to a register disposed on the input side of the combinational circuit on one clock input to a register is determined. After the input pattern II is scanned in, the input pattern I is supplied to the combinational circuit by providing two clocks. The test path is thereby formed. Then, a change in the Logic State of the test path is outputted from the combinational circuit, and the result of the output is set on the second clock. Thereafter, the result is scanned out, for comparison with an expected value. On the basis of the comparison, a pass or fail of the delay in the test path is checked.

FIGS. 6 to 9 are block diagrams for explaining the AC test for measuring a delay of a semiconductor integrated circuit device in which a scan path circuit is arranged.

Referring to FIG. 6, reference numerals 10₁ to 10₈ designate flip-flops that compose a scan path. In the scan mode or scan-enabled mode, each flip-flop latches a signal (pattern) fed to a scan input terminal SIN, synchronized with a scan clock signal to output the latched signal from a scan output terminal SO. The signal output from a scan output terminal SO is fed to the scan input terminal SIN of a flip-flop located in a subsequent stage.

The scan output terminal SO of a flip-flop 10₈ located in the last stage of plurality of flip-flops that are connected serially or in the form of a scan chain, is connected to a scan out terminal which is an external terminal of the semiconductor integrated circuit device. Each of these flip-flops has a scan mode (scan-enabled) terminal not shown. When a signal applied to the scan mode terminal (not shown) that is provided as an external terminal of the semiconductor integrated circuit device indicates a scan mode, the flip-flop latches a signal applied to the scan input terminal SIN triggered by the transition of an input scan clock. On the other hand, when a signal applied to the scan mode terminal (not shown) indicates the normal (scan-disabled) mode, the flip-flop latches the signal applied to a data input terminal D triggered by the transition of an input clock.

A combinational circuit 20 is provided between a register made up of the flip-flops 10₁ to 10₃ and a register made up of the flip-flops 10₄ to 10₆. Further, as a combinational circuit provided between a register made up of the flip-flops 10₄ to 10₆ and a register made up of the flip-flop 10₇, a circuit made up of an AND circuit 21, a NAND circuit 22, and an AND circuit 23 is provided.

In FIG. 6, the number of the flip-flops that compose the scan path is set to eight only for convenience sake and for ease of description. Also, the number of flip-flops in each of the registers, which respectively comprise the flip-flops 101 to 103 and the flip-flops 104 to 106, is not limited to three.

In the examples to be described below, a measurement path is a path in which the beginning node is an output terminal Q of the flip-flop 10₅ and the termination node is the data input terminal D of the flip-flop 10₇. The delay to be measured is a propagation delay tpHL from a rise (a transition from a low level to a high level) of an output signal outputted from the output terminal Q of the flip-flop 10₅ to a fall (a transition from a high level to a low level) of a signal which is fed to the data input terminal D of the flip-flop 10₇.

When executing a device testing, a semiconductor integrated circuit device under test is first set to the scan mode by means of a LSI tester. Then, initialization patterns are serially transferred from the scan-in terminal to the flip-flops or scan path registers that constitute a scan path in synchronization with a scan clock.

The status of the flip-flop 10₅ of which the output terminal is connected to the input node of the measurement path is set to a logic value “0”.

Then, pattern setting is conducted to the scan path so that the signal applied to the data input terminal D of the flip-flop 10₅ is set to take a logic value “1”.

Then, the status of the flip-flop 10₇ of which the data input terminal D is connected to the output terminal node of the measurement path is set to the logic value “1”.

The signal applied to the data input terminal D of the flip-flop 10₅ is made so as to take the logic value “1” by setting predetermined values to the flip-flops forming a register, output signals of which are provided to the combinational circuit 20. The predetermined values are determined by the logic conducted by the combinational circuit. As shown in FIG. 6, one of output signals outputted from the combinational circuit 20 is applied to the data input terminal D of the flip-flop 10₅, while the combinational circuit 20 receives parallel output signals from the flip-flops 10₁ to 10₃ forming a first scan register which is located in a stage preceding to a second scan register comprised of the flip-flops 10₄ to 10₆ which includes the flip-flop 10_{5.}

Accordingly, the flip-flops 10₁ to 10₃ are set to their initial values, respectively so that the signal to be supplied to the data input terminal D of the flip-flop 10₅ takes on the logic value “1”.

With regard to the pattern supplied from the scan-in terminal for setting the flip-flops that compose the scan path or the scan path registers, the respective inputs of the AND circuit 21, NAND circuit 22, and AND circuit 23 are set so that the measurement path constituted by the AND circuit 21, NAND circuit 22, and AND circuit 23 is activated, or a signal is propagated through the measurement path.

More specifically, the first and second input terminals of the AND circuit 21 receive the output of the flip-flop 10₄ and the output of the flip-flop 10₅ that constitutes the measurement path, respectively. The first and second input terminals of the NAND circuit 22 receive a signal from a path and the output of the AND circuit 21 that constitutes the measurement path, respectively. The first and second input terminals of the AND circuit 23 receive the output of the NAND circuit 22 that constitutes the measurement path and the output of the flip-flop 10₆. Referring to FIG. 6, the signal having the logic value “1” input to the first input terminal of the NAND circuit 22 is generated by the logic operation on the signal outputted from the register that comprises the flip-flops 10₄ to 10₆ in a logic circuit not shown. For transmission of the signal for measuring a delay through the AND circuit 21 that receives the output signal of the flip-flop 10₅, NAND circuit 22, and AND circuit 23, each circuit being arranged in the measurement path, the statuses of the flip-flops 10₄ to 10₆ are initialized so that the outputs of the flip-flops 10₄ and 10₆ take on the logic values “1” and the signal input to the first input terminal of the NAND circuit 22 takes on “1”. The initialization pattern for the flip-flops forming the scan path is automatically generated by an automatic test pattern generator (ATG).

Next, as shown in FIG. 7, the mode of the semiconductor circuit is set from the scan mode (scan-enabled mode) to the normal mode (scan-disabled mode) by means of the LSI tester, and two clocks having a clock period set in accordance with a predetermined test rate, for example, are supplied to a clock input terminal CK of the flip-flop. In the normal mode, each flip-flop does not latch a signal input to the scan input terminal SIN, but latches a signal input to the data input terminal D at the rising edge of the clock signal input. The LSI tester adjusts the clock period within the upper limit and the lower limit of a clock rate programmed so as to detect a delay in the measurement path.

At the rising edge of the first clock, the flip-flop 10₅ latches and outputs the signal of “1” applied to the data input terminal D. The output of the output terminal Q of the flip-flop 10₅ goes from a low level corresponding to “0” to a high level corresponding to “1”. At this point, in response to the rise transition of the output of the flip-flop 10₅ from “0” to “1”, the output of the AND circuit 21 is changed from “0” to “1”. In response to the rise transition of the output of the AND circuit 21 from “0” to “1”, the output of the NAND circuit 22 is changed from “1” to “0”. Then, in response to the fall transition of the output of the NAND circuit 22 from “1” to “0”, the output of the AND circuit 23 is changed from “1” to “0”. Then, the signal propagates through the measurement path extending from the output terminal of the flip-flop 10₅ to the data input terminal D of the flip-flop 10₇.

At the rising edge of the second clock, the flip-flop 10₇ connected to the termination node of the measurement path latches the signal input to the data input terminal D of the flip-flop 10₇.

Next, as shown in FIG. 8, the semiconductor integrated circuit device is set to the scan mode again by means of the LSI tester. Then, the flip-flops 10₁ to 10₈ in the device are connected in series, the scan clocks are supplied to the flip-flops 10₁ to 10₈, and the statuses (status monitoring patterns) of the flip-flops 10₁ to 10₈ are outputted serially from the flip-flop 10₈ close to the scan-out terminal. Upon reception of the serial output of the scan-out terminal, the LSI tester compares the status of the flip-flop that latches the output of the combinational circuit, with a pattern of an expected value. In this example, among the patterns outputted from the scan-out terminal, the value of the flip-flop 10₇ is compared with the expected value of “0”.

If the logic value of the flip-flop 10₇ coincides with the expected value as the result of comparison, or the result of comparison is a pass, it means that the flip-flop 10₇ normally latches the signal applied to its data input terminal on the second clock in the normal mode and that the delay in the measurement path is shorter than one period of the input clock. Namely, the signal from the output terminal of the flip-flop 10₅ propagates to the data input terminal D of the flip-flop 10₇ during a time less than one clock period. On contrast therewith, if the output value of the flip-flop 10₇ does not coincide with the expected value, it means that the delay tpHL in the measurement path is longer than the period of the input clock.

FIGS. 9a, 9b, and 9c are illustrations showing timing of the test described above. FIG. 9a shows the timing of a scan mode signal, and FIG. 9b shows the timing of the clock. In an example shown in FIG. 9a, when the scan mode signal is at a high level, the semiconductor integrated circuit device is in the scan mode or in the scan-enabled state, while the scan mode signal is at a low level, the semiconductor integrated circuit device is in the normal mode or in the scan-disabled state. In an example shown in FIG. 9b, the scan clock and the clock in the normal mode are input into the same terminal. The LSI tester changes the clock period according to whether the semiconductor integrated circuit device is in the normal mode or scans mode. In an example shown in FIG. 9c, a timing diagram for the clock in the normal mode and the scan clock input from different external terminals is shown. As shown in FIG. 9c by way of timing operations, the scan clock and the normal clock input from different external terminals are supplied to the selector of the semiconductor integrated circuit device. When the semiconductor integrated circuit device is in the scan mode, the scan clock is selected, whereas when the semiconductor integrated circuit device is in the normal mode, the normal clock is selected to be supplied to the clock input terminal CK of the flip-flop shown in FIGS. 8 through 9.

A series of processes for setting the initialization patterns in the scan mode (1) (corresponding to the operation in FIG. 6), setting the semiconductor integrated circuit to the normal mode (2) (corresponding to the operation in FIG. 7), and reading out the status monitoring patterns in the scan mode (3) (corresponding to the operation in FIG. 8) are executed, as shown in FIG. 9. Among the statuses of the flip-flops serially read out, if the output of the flip-flop 10₇ coincides with the expected value of “0”, the following processes are executed. Namely, setting the initialization patterns in the scan mode (1), setting the semiconductor integrated circuit device to the normal mode (2) in which the clock period is set to be shorter, and reading out the status monitoring patterns in the scan mode (3) are performed. Then, the process of comparison that checks whether the output of the flip-flop 10₇ among the flip-flops of which the statuses have been serially read out coincides with the expected value is executed. In a series of test operations in the scan mode (1), normal mode (2), and scan mode (3), the clock period in the normal mode (2) is reduced one by one, until the output of the flip-flop 10₇ does not coincide with the expected value, or the result of comparison becomes a fail.

In the operation in the normal mode (2), if a delay in the measurement path or a propagation delay of the signal from the rise of the output of the flip-flop 10₅ to the fall of the input to the data input terminal of the flip-flop 10₇ is shorter than the clock period tCK1 of the normal clock input, the signal propagates to the data input terminal D of the flip-flop 10₇ and goes to a low level before the rising edge of the second clock, as shown in FIG. 10. If the flip-flop 10₇ latches the signal input to its data input terminal D on the second clock, the output of “0” is supplied, so that it coincides with the expected value of “0”. After the output of the flip-flop 10₇ coincides with the expected value, the clock period is reduced to tCK2 as shown in FIG. 10 in the operation in the normal mode (2). Then, suppose that a delay in the measurement path becomes equal to or longer than the clock period. Then, when the flip-flop 10₇ latches the signal input to its data input terminal D at the rising edge of the second clock, the signal does not propagate to the data input terminal of the flip-flop 10₇ yet, so that the flip-flop 10₇ latches and outputs the logic value “1”. Accordingly, the output of the flip-flop 10₇ does not coincide with the expected value of “0”. It means that a propagation delay in the measurement path can be measured from the clock period tCK in the normal mode (2) at the time when the result of comparison with the expected value has changed from the pass to the fail. Alternatively, after the output of the flip-flop 10₇ does not coincide with the expected value, the clock period in the normal mode (2) is increased one by one. Then, with this arrangement, a propagation delay of the signal in the measurement path may also be measured from the clock period in the normal mode (2) at the time when the result of comparison with the expected value has changed from the fail to the pass. Still alternatively, a delay may also be measured by a binary search method.

In the conventional delay test (AC test that uses the scan path) described above, a pattern associated with the signal having the logic value of “1” input to the input terminal of the NAND 22 in FIG. 6 is provided only to the measurement path and the path for activating the measurement path. In performing the test, no signals are set for the paths other than those.

In the AC test that uses the scan path, delay measuring patterns are automatically generated by an ATG or an ATPG (Automatic Test pattern Generator). FIG. 5 is a block diagram showing a conventional system that generates delay test patterns by means of a Delay_test ATG. A STA (Static Timing Analyzer) 201 is a software tool that adds up propagation delays of a signal that passes through the circuit elements and paths of an LSI to calculate a propagation delay in a signal path without the use of a logic simulation, and outputs delay measurement path information 202. Delay measuring patterns (Delay_test patterns) 205 is automatically generated by a delay_test ATG 204 on the basis of the delay measurement path information 202 and circuit information 203 on circuit elements and their connecting information.

The Delay_test ATG 204 that automatically generates delay test patterns generates the delay test patterns 205 on the basis of the measurement path information alone. In the Delay_test ATG 204, the mechanism for generating patterns for the paths other than the measurement path is not installed.

For this reason, the actual crosstalk influence could not be checked for the paths such as the one extending in parallel with the measurement path, that the influence by a crosstalk to the measurement path couldn't be neglected.

### SUMMARY OF THE DISCLOSURE

Accordingly, it is an object of the present invention to provide a method, an apparatus, and a computer program product for automatically generating patterns that also includes patterns for a path, of which crosstalk influences to a measurement path, so as to make it possible to measure the effect of the path that has a crosstalk to the measurement path, in a delay test in a semiconductor integrated circuit device.

In accordance with one aspect of the present invention, when generating a test pattern for testing a semiconductor integrated circuit device including a scan path circuit, a measurement path for measuring a delay and other path that exerts influence on crosstalk to the measurement path are determined on the basis of layout information of the semiconductor integrated circuit device, then a pattern for measuring the delay is fed to the measurement path, and a pattern for exerting influence on crosstalk to the measurement path is generated for the other path.

In accordance with another aspect of the present invention, in a device testing of a semiconductor integrated circuit device, when a signal for measuring a delay is applied to a measurement path, a signal in phase or in opposite phase with the signal applied to the measurement path is also applied to the path that influences crosstalk to the measurement path, and then the propagation delay of the signal that propagates through the measurement path under the influence of crosstalk is measured.

In accordance with another aspect of the present invention, the signal level of the path that influences crosstalk to the measurement path is set to a fixed value, and the delay of the signal that propagates through the measurement path is measured. On the basis of a difference between the delay in the measurement path when the path that influences crosstalk to the measurement path is set to a fixed value and delay in the measurement path when the signal has been applied to the path that influences crosstalk to the measurement path, the influence of crosstalk is evaluated.

In accordance with another aspect of the present invention, in an AC test that uses a scan path, a signal for measuring a delay is applied to the measuring path of a combinational circuit disposed between a plurality of registers, each of which comprises one or plural flip-flops composing a scan path, from a flip-flop connected to the input side of the measurement path. A signal in phase or in opposite phase with the signal applied to the measurement path is also applied to a path that influences crosstalk to the measurement path, from a flip-flop connected to the input side of the path. Then, the status of a flip-flop that samples the output of the measurement path is compared with an expected value. The delay in the measurement path is thereby measured.

Still other objects and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a block diagram showing a system according to a first embodiment of the present invention;

FIGS. 2a and 2b comprise a block diagram and a graph, respectively, schematically showing a test according to the first embodiment of the present invention;

FIGS. 3a and 3b comprise a block diagram and a graph, respectively, schematically showing a test according to a second embodiment of the present invention;

FIGS. 4a and 4b is a table and a block diagram, respectively, showing an example of measurement path information and aggressor path information according to the first embodiment of the present invention;

FIG. 5 is a block diagram showing the configuration of a conventional delay test pattern generation system;

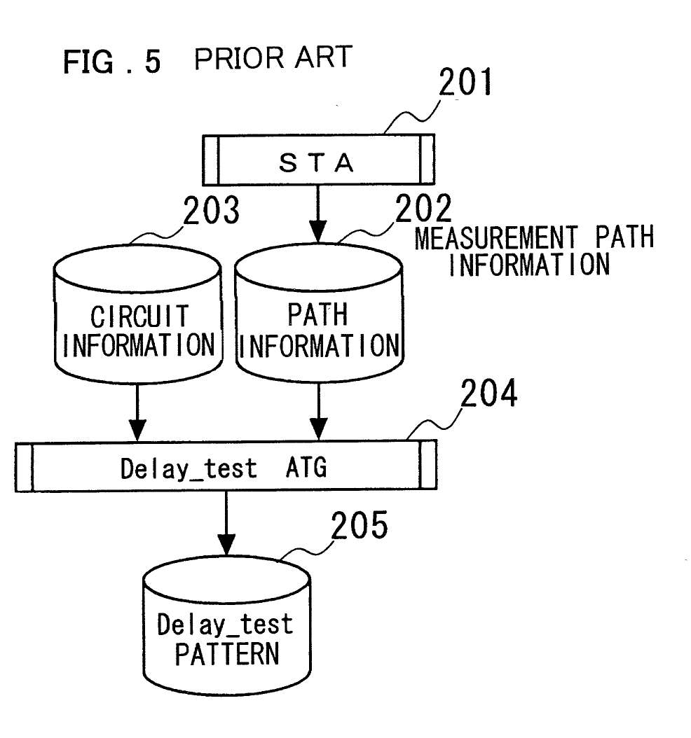

FIG. 6 is a block diagram schematically showing a delay test for a scan path circuit;

FIG. 7 is a block diagram schematically showing the delay test for the scan path circuit;

FIG. 8 is a block diagram schematically showing the delay test for the scan path circuit;

FIGS. 9a, 9b, and 9c are illustrative diagrams showing timing for the scan path circuit; and

FIGS. 10a, 10b, and 10c comprise a timing diagram showing a relationship between a clock and a propagation delay in delay measurement.

### PREFERRED EMBODIMENTS OF THE INVENTION

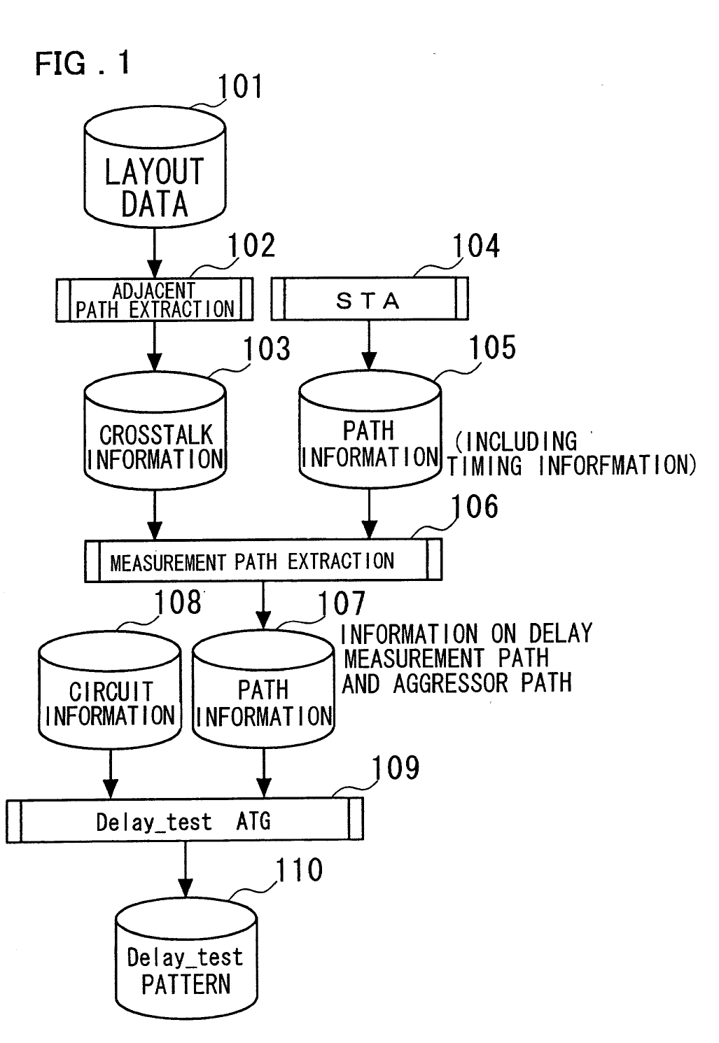

Preferred embodiments of the present invention will be described. FIG. 1 is a block diagram schematically showing the configuration and processes of a system in accordance with an embodiment of the present invention. Referring to FIG. 1, in accordance with the embodiment of the present invention, when automatically generating test patterns for measuring a delay in a semiconductor integrated circuit (LSI) that has a scan path, an adjacent path extraction process (102) is performed on the basis of layout information (101) of the semiconductor integrated circuit. Crosstalk information (103) on a path that exerts influence on crosstalk to the measurement path is thereby extracted. That is, in the adjacent path extraction process (102), one or plural paths adjacent to the measurement path are extracted on the basis of the layout information (101). A path that might exert influence on crosstalk to the measurement path is thereby extracted and outputted as a crosstalk information. This crosstalk information is extracted on the basis of conditions such as design information on lines/spaces, the relative dielectric constant of an insulating film, and the length of the path that extends in parallel with the measurement path. Incidentally, a critical path or a path corresponding to the critical path is selected as the measurement path.

In a process (106), the crosstalk information (103) and path information (105) are referenced, so that path information (107), also referred to as the information on the delay measurement path and an aggressor path, which comprises delay measurement path information and information on the path that exerts influence on crosstalk to the delay measurement path, or the aggressor path, is generated. The delay measurement path information comprises a combination of node information on the delay measurement path and transition information of a signal at respective nodes.

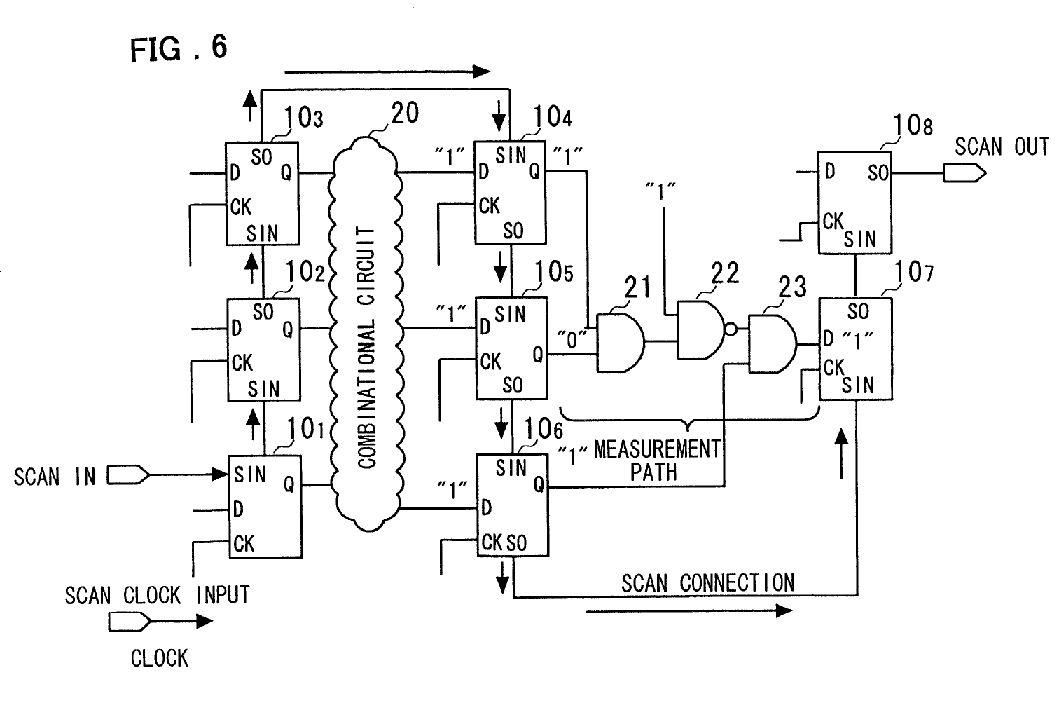

Then, on the basis of circuit information (108) and the information (107) on the delay measurement path and the aggressor path, delay test patterns (110) are automatically generated by a Delay_test ATG (109). The delay test patterns (110) include a pattern for outputting a signal that should be set for allowing the signal for measuring the delay supplied to the measurement path to propagate through the measurement path, from a flip-flop connected to a register on the input side of the measurement path. The delay test patterns (110) further includes an initialization pattern for outputting a signal that should be set so as to be supplied to the aggressor path for influencing crosstalk to the measurement path, from a flip-flop connected to a register on the input side of the aggressor path. As described with reference to FIGS. 6 through 9, the Delay_test ATG (109) also generates an initialization pattern for a flip-flop connected to the output end of the measurement path, and a pattern for setting flip-flops so as to cause signals to propagate through the measurement path and the aggressor path automatically.

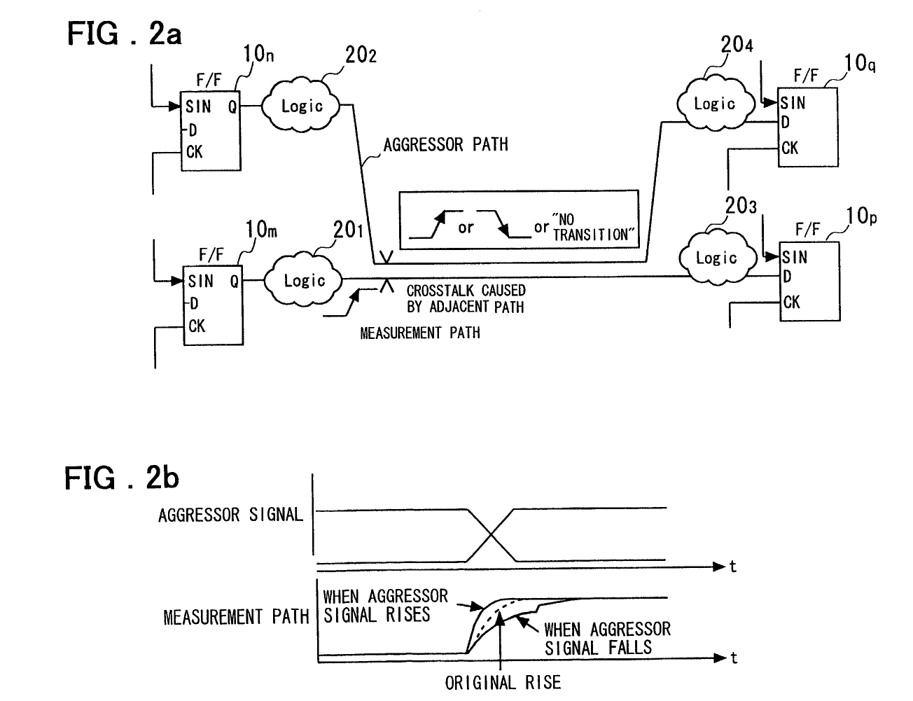

When the AC test for measuring a delay is conducted on the semiconductor integrated circuit in accordance with the embodiment of the present invention, the generated test patterns are set for the flip-flops (scan path registers) that compose a scan path to conduct the test. Namely, the semiconductor integrated circuit device under test is set to the scan mode. Then, initialization patterns are supplied from the scan-in terminal of the semiconductor circuit. The initialization patterns comprise a pattern for initializing a flip-flop (10m in FIG. 2) connected directly or through a logic circuit to the input terminal of the measuring path on which a delay measurement is performed. The initialization patterns further comprise a pattern for initializing a flip-flop (10n in FIG. 2), the output of which is connected directly or through a logic circuit (20₂ in FIG. 2) to the input terminal of the aggressor path that influences crosstalk to the measurement path. The initialization patterns still further comprise a pattern for setting flip-flops that should be set to predetermined states so as to cause the signal to propagate through the measurement path and the aggressor path. The combinational circuit receives the output from a register comprised of one or plural flip-flops that constitutes the scan path and the output from the combinational circuit is connected to the input of a register comprised of a flip-flop that constitutes the scan path.

Then, the flip-flop of a register located in a front stage of the flip-flop 10m, not shown, is set so that the initial state of the flip-flop 10m is set to the logic value “0” and a signal supplied to the data input terminal D of the flip-flop 10m takes on the logic value “1” when the signal for measuring the delay that has been supplied to the measurement path goes to a high level from a low level. The register located at the front stage of the flip-flop 10m supplies an output signal to the input terminal of the combinational circuit that supplies an output signal to the data input terminal D of the flip-flop 10m.

The flip-flop of a register located at the front stage of the flip-flop 10n, not shown, is set so that the initial state of the associated flip-flop 10n is set to the logic value “1” and the signal supplied to the data input terminal D of the flip-flop 10n takes on the logic value “0” when the signal that has been input as an aggressor signal rises to a high level. The register located at the front of the flip-flop 10n supplies an output signal to the input terminal of a combinational circuit that supplies an output signal to the data input terminal D of the flip-flop 10n.

Then, the semiconductor integrated circuit device under test is set to the normal mode from the scan mode by means of a LSI tester. The flip-flop 10m in FIG. 2 that supplies the signal to the input terminal of the measurement path latches the signal applied to its data input terminal D at the rising edge of the first clock. Then, the output terminal of the flip-flop 10m undergoes a transition from the initial state to a second state to bring about signal propagation through the measurement path. The flip-flop 10n in FIG. 2 that supplies the signal to the input terminal of the aggressor path latches the signal applied to its data input terminal D at the rising edge of the first clock. Then, the output terminal of the flip-flop 10n undergoes a transition, thereby bringing about signal propagation through the aggressor path. A flip-flop 10p in FIG. 2 that receives from its data input terminal D the signal at the output terminal of the measurement path latches the signal applied to its data input terminal D at the rising edge of the second clock.

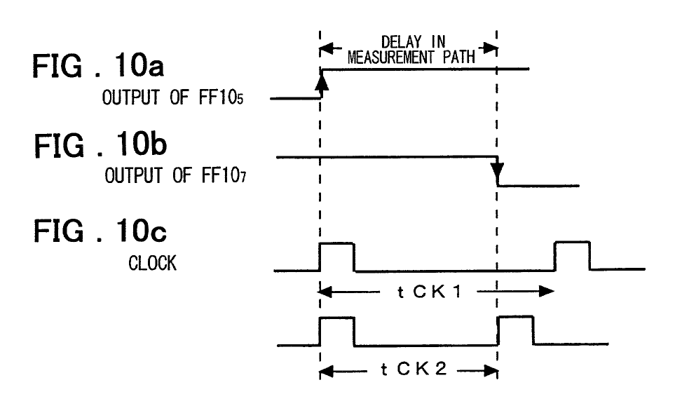

Then, the semiconductor integrated circuit device under test is set to the scan mode again by means of the LSI tester. Thereafter, the values of the flip-flops that constitute the scan path are serially read out from the scan-out terminal of the semiconductor integrated circuit device. Then, the value of the flip-flop that receives from its data input terminal the signal at the output terminal of the measurement path is compared with an expected value. If the result of comparison is a pass, the clock period is reduced by a predetermined period of time. If the result of comparison is a fail, the clock period is increased by a predetermined period of time. Then, the above-mentioned steps are executed, and the clock period at the time when the result of comparison has changed from the pass to the fail, or from the fail to the pass is determined to be the delay in the measurement path under the influence of crosstalk. Detection of the delay in the measurement path is performed, following the procedural steps that are the same as those used in the conventional delay test method described with reference to FIGS. 6 through 10.

In the embodiment mode of the present invention, the signal for setting the path that influences crosstalk to the measurement path to a fixed value in the scan mode is set, for the flip-flop connected to the path. Then, two clocks are supplied in the normal mode to cause the flip-flop of which the data input terminal is connected to the measurement path to latch the signal at the end of the measurement path. Then, the statuses of the flip-flops are serially read out in the scan mode. A comparison with the expected value is thereby made. The delay in the measurement path is measured from the clock period at the time when the result of comparison has changed from the pass to the fail. Then, on the basis of a difference between the above delay time and the delay time measured when the signal is supplied to the path that influences crosstalk to the measurement path, the influence of crosstalk such as an increase in the delay time in the measurement path resulting from crosstalk can be quantitatively evaluated.

For a further detailed explanation the embodiment of the present will be described with reference to the drawings. FIG. 1 is the schematic diagram for explaining the system and the processes according to a first embodiment of the present invention. Referring to FIG. 1, adjacent path extraction process 102 is performed on the basis of layout information 101 on a semiconductor integrated circuit device to extract crosstalk information 103 which is a wiring information on a path that exerts influence on crosstalk to a measurement path. Then, in the process 106, the path information 107 that comprises a delay measurement path information and information on the path that exerts influence on crosstalk to the delay measurement path (termed an aggressor path) are generated on the basis of the crosstalk information 103 and the path information 105. The path information 107 is also referred to as the path information on the delay measurement path and the aggressor signal path. The delay measurement path information includes a combination of the names of the nodes constituting the delay measurement path and the transition information of the signal at the nodes.

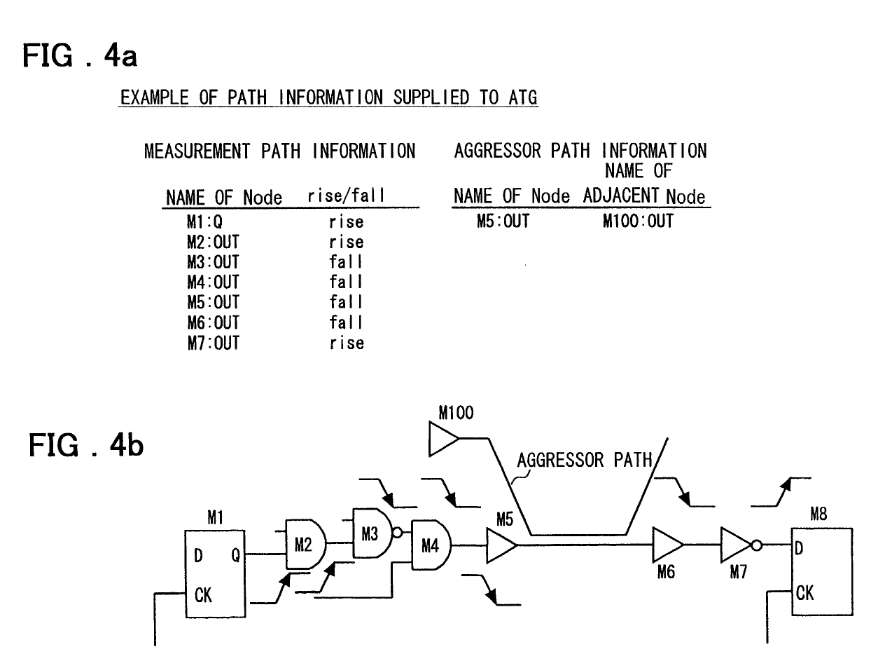

FIGS. 4a and 4b show a table and an illustrative circuit diagram for explaining a specific example of the path information 107 on the delay measurement path and the aggressor path. FIG. 4a is the table showing a result of extraction of the measurement path and the aggressor path (aggressor_path) in a circuit illustrated in FIG. 4b. Referring to FIG. 4b, M1 and M8 are flip-flops that constitute a scan path. A path that extends from an output terminal Q of the flip-flop M1 to the data input terminal D of the flip-flop M2 is the measurement path. In the measurement path information, the names of the nodes that constitutes the measurement path and the transition types (rise/fall) of the signal that propagates through the measurement path are extracted.

In the aggressor path information, a path that extends in parallel with an output OUT of a node M5 is extracted, and an output OUT of a node M100 is detected as the name of a node adjacent to the node M5.

The Delay_test ATG 109 for automatically generating test patterns for a delay test searches the combinational circuit in the input direction of the node M100 on the basis of the circuit information 108, the information on the measurement path and the aggressor path information. The Delay_test ATG 109 then finds a flip-flop for setting the output OUT of the node M 100 that constitutes the aggressor path to an initial state. Then, the Delay_test ATG 109 finds out flip-flops of which the statuses should be set so as to supply the aggressor signal from the corresponding flip-flop. Then, the delay test ATG 109 generates a pattern for supplying a signal which is in opposite (reverse) phase or in-phase with the transition direction of the output OUT of the node M5 which belongs to the measurement path.

The Delay test ATG 109 generates an initialization pattern that should be set so as to change the output OUT of the node M5 of the measurement path from a high level to a low level as well.

Namely, when the output terminals of a combinational circuit of a preceding stage are connected to the data input terminals of the flip-flops 10m and 10n in FIG. 2, output terminals of which provide the signals to the input terminals of the measurement path and the aggressor path, the Delay_test ATG 109 generates a pattern for initializing the flip-flops with their output terminals connected to the input terminals of the combinational circuit of the preceding stage to predetermined states. By setting the flip-flops with their output terminals connected to the input terminals of the combinational circuit of the preceding stage to the predetermined states, signals in the states different from the ones used for initialization of the flip-flops 10m and 10n in FIG. 2 are supplied to the data input terminals of the flip-flops that provides signals to the input terminals of the measurement path and the aggressor path from their output terminals. The flip-flops causes the output signals to change synchronized with the transition of the clock signal.

Then, in order to activate the measurement path and the aggressor path, the Delay_test ATG 109 generates an initialization pattern that should be set for the associated flip-flops.

The initialization patterns set for the flip-flops connected in series for constituting the scan path are serial patterns serially input from the scan-in terminal of the semiconductor integrated circuit.

In the embodiment described above, the adjacent path extraction process 102, STA process 104, measurement path extraction process 106, and the Delay_test ATG 109 for automatically generating delay test patterns are all implemented by a computer program executed on a computer.

FIG. 2a is a schematic diagram showing a relationship between the measurement path and the aggressor path, and FIG. 2b is a diagram showing operation timing according to the first embodiment of the present invention. A further description will be given about the measurement path and the aggressor path with reference to FIG. 2. The pattern for setting the flip-flop 10m which has its output terminal connected to the node that constitutes the input terminal of the measurement path, the flip-flop 10p which has its input terminal connected to the node that constitutes the output terminal of the measurement path, the flip-flop 10n which has its output terminal connected to the node that constitutes the input terminal of the aggressor path, and a flip-flop 10q which has its input terminal connected to the node that constitutes the output terminal of the aggressor path to predetermined initial states is generated. On this occasion, the flip-flops that should be set for activating the measurement path and the aggressor path, or propagation of the signals through the measurement path and the aggressor path are set to predetermined states. Further, as described with reference to FIG. 6, let us suppose that there exists a combinational circuit that provides an output signal to the data input terminal D of the flip-flop 10m having its output terminal connected to the node that constitutes the input terminal of the measurement path, and that there exists a flip-flops that constitutes a register which provides in the normal mode data to the combinational circuit (refer to reference numeral 20 in FIG. 6). In other words, if the combinational circuit 20 is arranged in a preceding stage of the flip-flops 10₄ to 10₆ and the flip-flops 10₁ to 10₃ are arranged in a preceding stage of the combinational circuit 20, as illustrated in FIG. 6, in order to supply the signal for changing the node that constitutes the input terminal of the measurement path to other state, the initialization pattern for setting the flip-flops having their output terminals connected to the input terminals of the combinational circuit of the preceding stage to predetermined states is generated.

Two types of the initialization pattern for setting the flip-flop associated with the aggressor path are prepared: one is for causing the transition of the signal supplied to the aggressor path to be in phase with the transition of the signal supplied to the input terminal of the measurement path, and the other is for causing the transition of the signal supplied to the aggressor path to be in a reverse direction with the transition of the signal supplied to the measurement path. Further, a pattern is generated for setting the signal of the aggressor path to a fixed value with the value being held and unaltered. The Delay_test ATG 109 also generates a pattern for an expected value automatically.

When the semiconductor integrated circuit is tested by the LSI tester using the patterns generated by the Delay_test ATG 109, the semiconductor integrated circuit is first set to the scan mode (scan-enabled mode). Then, the serial patterns for supplying the delay measurement signal, aggressor signal, and the signal for activating the measurement path and the aggressor path are entered from the scan-in terminal and applied to the associated flip-flops of the registers that constitutes the scan path.

Then, the semiconductor integrated circuit is set from the scan mode to the normal mode (scan-disabled state). On the first clock, the flip-flop 10m, having its output terminal connected to the node that constitutes the input terminal of the measurement path latches the signal applied at a data input terminal, and changes its output signal from the initial state to other state. At this point, the flip-flop 10n having its output terminal connected to the node that constitutes the input terminal of the aggressor path changes its output in the direction opposite to the output of the flip-flop 10m. That is, when the output signal of the flip-flop 10m rises, the output of the flip-flop 10n falls. Then, on the second clock, the flip-flop 10p having its data input terminal connected to the node that constitutes the output terminal of the measurement path, latches the signal at its data terminal. When the output signal of the flip-flop 10m rises, the output of the flip-flop 10n falls. The signal applied to the aggressor path changes in the direction opposite to the transition direction of the signal applied to the measurement path. Then, due to the influence of crosstalk or capacitive coupling caused by the aggressor path, the rise time of the signal applied to the measurement path for measuring the delay is delayed.

Then, the semiconductor integrated circuit is set to the scan mode to read out the status value of the flip-flop that constitutes the scan path, for comparison with the expected value. When the result of comparison is a pass, the clock period is reduced to execute the steps described above. Then, the clock period at the time when the result of comparison has changed from a pass to a fail, or from a fail to a pass is determined to be the delay in the measurement path under the influence of crosstalk.

Next, in the case of the signal applied to the aggressor path, which changes in-phase with the signal applied to the measurement path as well, the tests of setting initialization patterns for the flip-flops that constitute the scan path, supplying two clocks in the normal mode, and reading out the status monitoring patterns of the flip-flops that constitute the scan path are executed. The clock period at the time when the result of comparison has changed from a pass to fail or from fail to a pass is measured and determined as the delay in the measurement path. In this case, as shown in FIG. 2b, when the output signal of the flip-flop 10m rises, the output of the flip-flop 10n (the signal propagating through the aggressor path) rises, and the signal applied to the aggressor path transitions undergoes a transition in the same direction as the signal applied the measurement path. The rise time of the signal supplied to the measurement path is reduced due to the influence of crosstalk (capacitive coupling) caused by the aggressor path.

Next, only the signal applied to the measurement path is transitioned, and the level of the aggressor path is set to a fixed state. Then, a delay time in the measurement path is measured in the same manner.

On the basis of a difference between the delay time (in terms of clock period) in the measurement path which is detected when the aggressor path is not activated and the delay time in the measurement path when the aggressor path is activated, the clock delay quantity, caused by the crosstalk when the aggressor path that influences crosstalk is activated, can be evaluated.

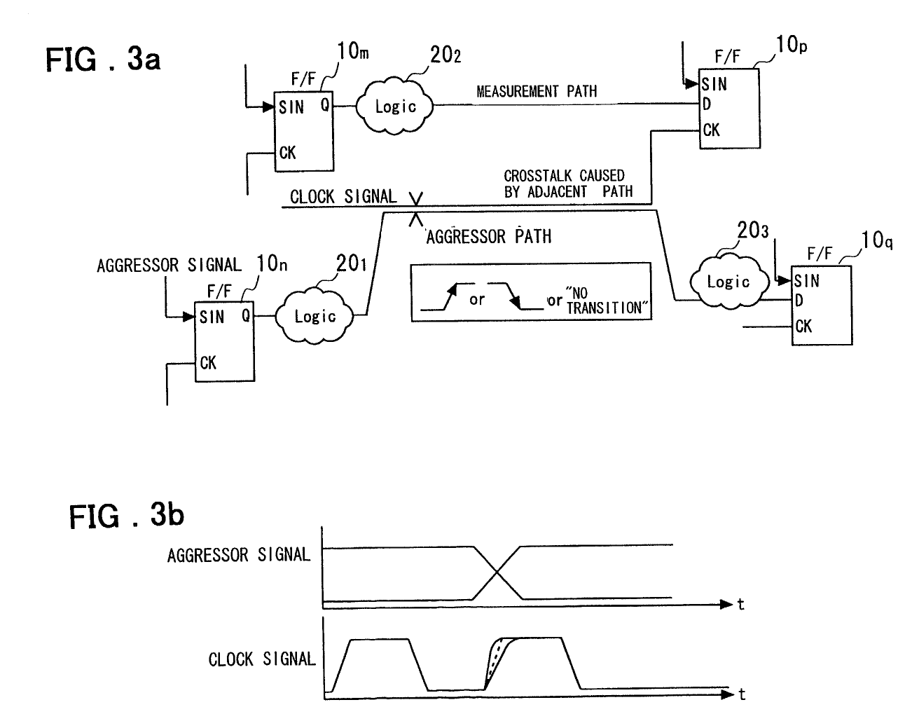

A second embodiment of the present invention will be described. FIGS. 3a and 3b are respectively a schematic diagram and a graph for explaining the second embodiment of the present invention. In the second embodiment of the present invention, the influence of crosstalk of an adjacent wiring on the clock signal is measured. The wiring which is placed adjacent to the clock signal wiring for supplying a clock to the flip-flop 10p that belongs to the measurement path and extends in parallel with the clock signal wiring (the aggressor path which exerts influence on crosstalk to the clock signal) is detected on the basis of the layout information of a semiconductor integrated circuit. Then, the information on the aggressor path that influences crosstalk to the clock signal is generated.

For the flip-flop that samples data applied at an data input terminal thereof at a rising edge of the input clock signal, three types of patterns for the signal supplied to the aggressor path (termed aggressor signal) are generated. Namely, the pattern for the aggressor signal that rises in the same direction of transition with the rise of the clock signal, the pattern for the aggressor signal that falls in the direction opposite to the rise of the clock signal, and the pattern for the aggressor signal that does not have any transition are generated.

As shown in FIG. 3b, when the signal supplied to the aggressor path (termed also as aggressor signal) rises in phase with, or in the same direction of transition with the clock signal, the rise time of the clock signal is reduced due to the influence of crosstalk (capacitive coupling). On the other hand, when the aggressor signal falls in the direction opposite to the transition of the clock signal, the rise time of the clock signal is delayed due to the influence of crosstalk (capacitive coupling).

When the rise time of the clock signal that defines a latch timing of the flip-flop 10p is reduced, erroneous data is sometimes sampled in conjunction with the setup time of the flip-flop. When the rise time of the clock signal that defines a latch timing of the flip-flop 10p is delayed, the propagation delay of data cannot be detected accurately due to the delay of the clock signal. It also holds true when propagation of the signal to the data input terminal D of the flip-flop 10p is delayed, falling behind the original specified time.

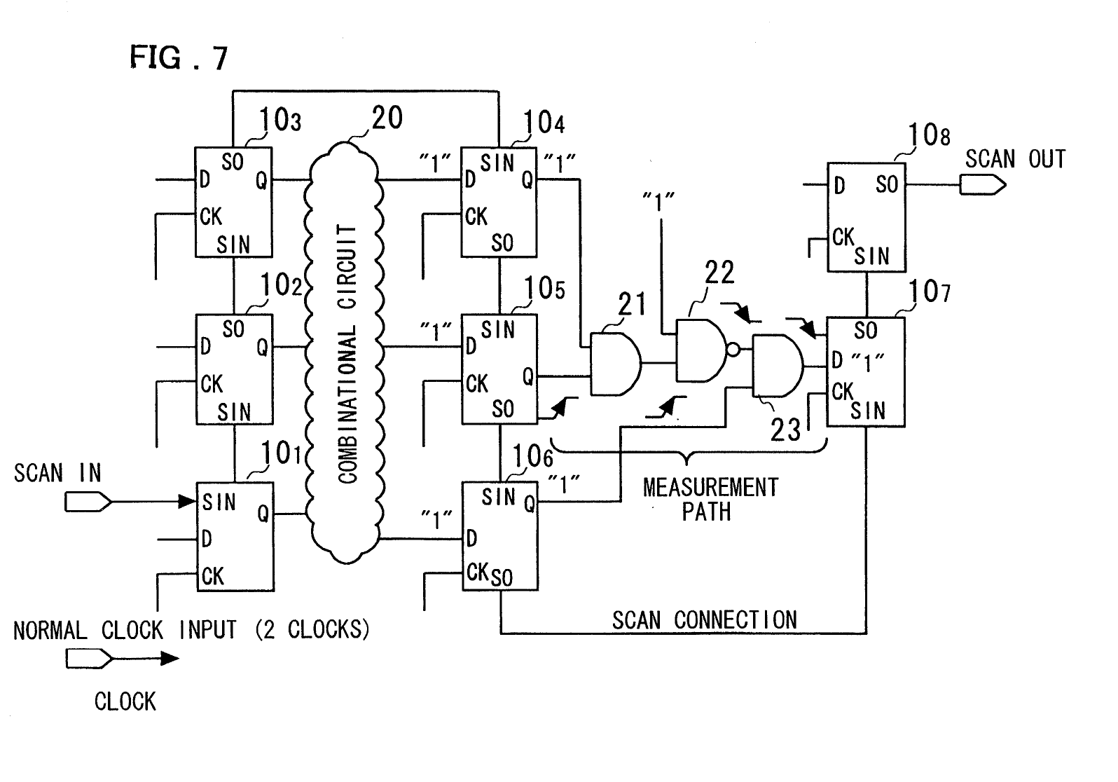

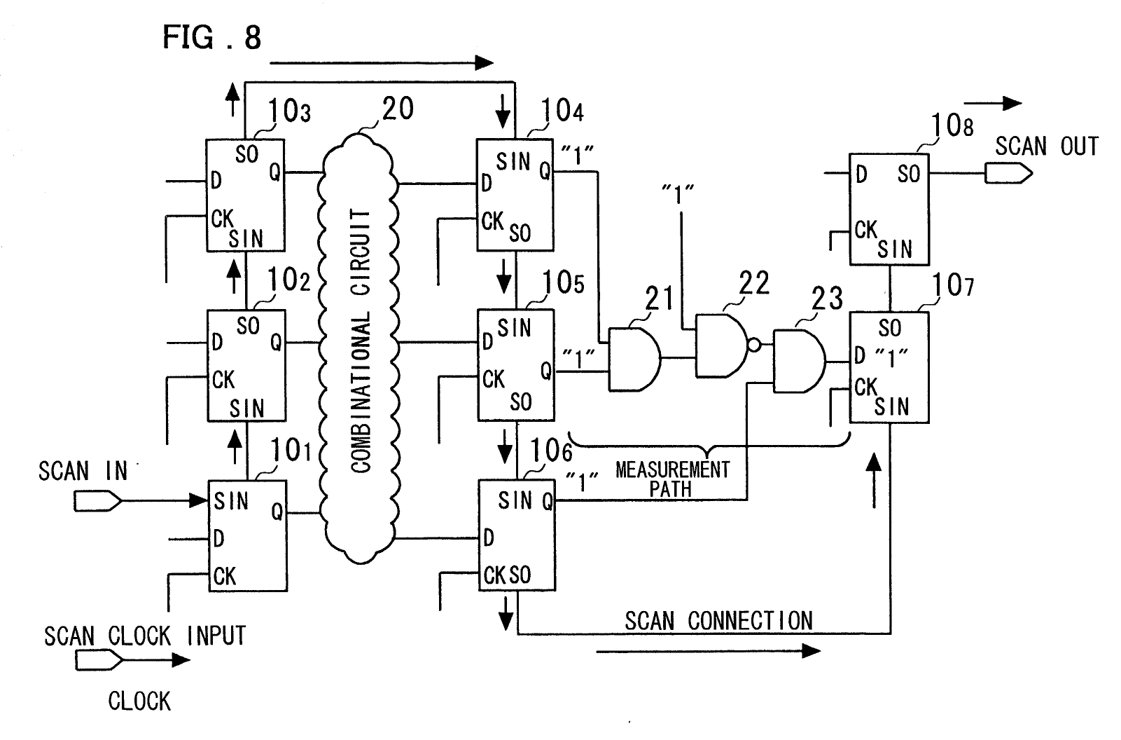

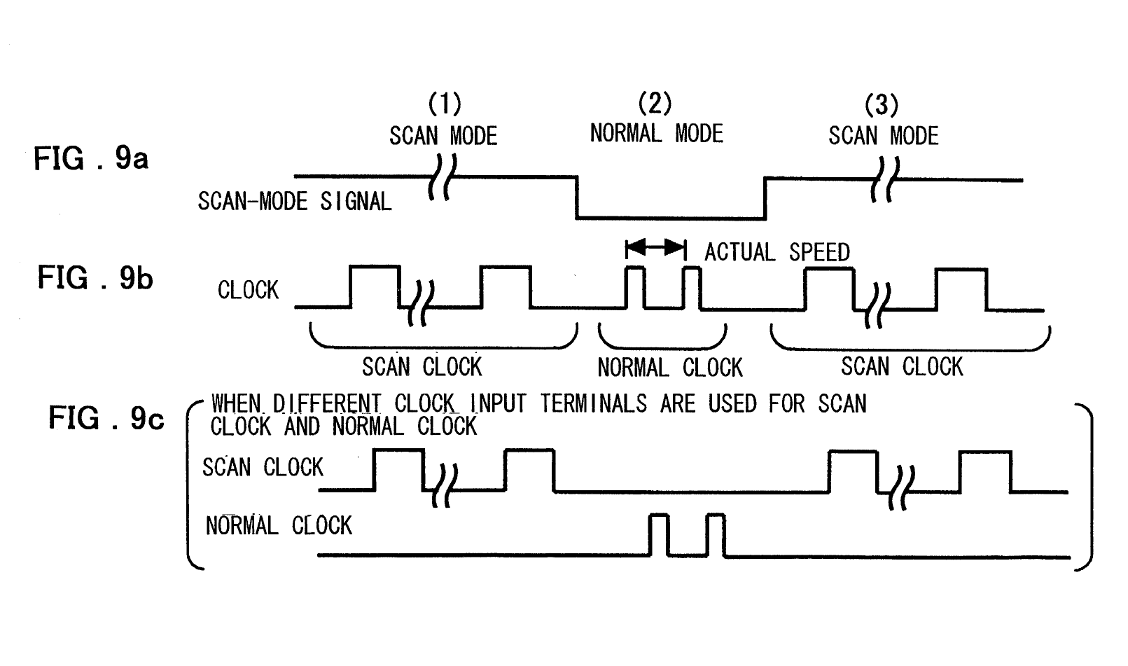

In this embodiment, the initialization pattern is supplied to the flip-flops associated the measurement path and the flip-flops associated with the aggressor path in the scan mode (refer to FIG. 6 and (1) in FIG. 9). Then, two clocks are supplied in the normal mode (refer to FIG. 7 and (2) in FIG. 9), and then the values of the flip-flops that constitutes the scan path is read out serially in the scan mode (refer to FIG. 8 and (3) in FIG. 9). The value of the flip-flop 10p is compared with the expected value, and the clock period at the time when the result of comparison has changed from a pass to fail is measured.

When the signal supplied to the aggressor path is set to a fixed value as well, the initialization pattern is supplied to the flip-flops associated with the measurement path, and to the flip-flops associated with the aggressor path in the scan mode. Then, two clocks are supplied in the normal mode, and the values of the flip-flops that constitute the scan path are read out serially in the scan mode. The value of the flip-flop 10p is compared with the expected value, and the clock period at the time when the result of comparison has changed from a pass to fail is measured. On the basis of a difference between the delay time (in terms of the clock period) in the measurement path detected when the aggressor path is not activated and the delay time in the measurement path when the aggressor path is activated, the quantity of delay (indicated by the clock period), caused by the crosstalk when the aggressor path that influences crosstalk is activated, can be evaluated.

In this embodiment, in the measurement path extraction process 106 in FIG. 1, the measurement path information that comprises a combination of nodes constituting the measurement path and transition information of the signal at the nodes is generated. If there is an aggressor path that exerts influence on crosstalk to the clock signal wiring for supplying a clock to the flip-flop connected to the measurement path exists, the aggressor path information comprising node information on the aggressor path is generated. On the basis of the circuit information 108 of the semiconductor circuit and the information 107 on the measurement path and the aggressor path, and the clock signal wiring information, the Delay_test ATG 109 automatically generates patterns. The patterns include the pattern for outputting the signal for measuring the delay from the flip-flop connected to the measurement path, the pattern for supplying to the aggressor path which has a crosstalk influence to the measurement path, the signal that exerts influence on crosstalk to the clock signal wiring from the flip-flop associated with the aggressor path, and the pattern for setting the flip-flops that should be set for allowing signals to propagate through the measurement path and the aggressor path to predetermined states.

While the present invention was described with reference to the above embodiments, the invention is not limited to the above embodiments. It will be understood that modifications and variations that could be made by those skilled in the art are included within the scope of the appended claims.

The meritorious effects of the present invention are summarized as follows.

As described above, according to the present invention, when conducting a delay test on a measurement path, a signal is set on a path that exerts crosstalk influence to the measurement path to measure a delay in the measurement path. The actual influence of crosstalk can be thereby evaluated.

Further, according to the present invention, when conducting the delay test on the measurement path, a pattern for supplying a signal to the path that exerts crosstalk influence to the measurement path is automatically generated. With this arrangement, reduction in test costs can be effected.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items might fall under the modifications aforementioned.

What is claimed is:

1. A method for testing a semiconductor integrated circuit, wherein, when a signal for measuring a delay is applied to a measurement path on which a delay test is conducted, a signal having a transition being in phase or in opposite phase with said signal for measuring a delay applied to said measurement path is applied to a path that influences crosstalk to said measurement path, thereby measuring a propagation delay time of said signal that propagates through said measurement path under the influence of crosstalk.

2. The method according to claim 1, further comprising the steps of:
supplying said signal for measuring a delay to said measurement path after a signal level of said path that influences crosstalk to said measurement path is set to a fixed value, thereby, measuring the propagation delay time of said signal for measuring a delay that propagates through said measurement path; and
performing a quantitative evaluation on the influence of crosstalk, on the basis of a difference between the propagation delay time measured after the signal level of said path that influences crosstalk to said measurement path is set to the fixed value and the propagation delay time of said signal for measuring a delay, measured with the signal applied to said path that influences crosstalk to said measurement path.

3. A method for testing a semiconductor integrated circuit in an AC test using a scan path, the method comprising the steps of:
receiving from a scan-in terminal of a scan path register a pattern for supplying a signal for measuring a delay to a measurement path on which a delay test is conducted and a pattern for supplying a signal having a transition being in phase or in opposite phase with said signal for measuring a delay to a path that influences crosstalk to said measurement path;
supplying said signal for measuring a delay to said measurement path and supplying the signal to the path that influences crosstalk to said measurement path from said scan path register; and
reading out a value of the scan path register that samples said signal at an end terminal of said measurement path, from a scan-out terminal to compare the value of said scan path register with an expected value, thereby measuring a delay time in said measurement path.

4. A method for testing a semiconductor integrated circuit having a scan path, the method comprising the steps of:
supplying a signal for measuring a delay to a measurement path of a combinational circuit from a flip-flop associated with said measurement path, the combinational circuit being disposed between a plurality of registers, each of which comprises one or plural flip-flops constituting the scan path, and also supplying to a path (termed an aggressor path) that influences crosstalk to said measurement path a signal having a transition being in phase or in opposite phase with said signal supplied to said measurement path from a flip-flop associated with the aggressor path; and
comparing a value of a flip-flop that samples the signal of an end terminal of said measurement path with an expected value, thereby measuring a delay time in said measurement path.

5. A method for testing a semiconductor integrated circuit having a scan path, the method comprising the steps of:
supplying a signal for measuring a delay to a measurement path in a combinational circuit from a flip-flop associated with said measurement path, the combinational circuit being disposed between a plurality of registers, each of which comprises one or plural flip-flops constituting the scan path, and also supplying to a path that influences crosstalk to a clock signal path a signal having a transition being in phase or in opposite phase with said clock signal, a clock to one or plural flip-flop associated with said measurement path being supplied through said clock signal path; and
comparing a value of the flip-flop that samples the signal at an end terminal of said measurement path with an expected value, thereby measuring a delay time in said measurement path.

6. The method according to claim 4, further comprising the steps of:
supplying a signal for setting said path that influences crosstalk to said measurement path to a fixed value from the flip-flop associated with said path so as to measure a delay time in said measurement path; and
evaluating an effect of crosstalk on the basis of a difference between the delay time in said measurement path measured after the signal for setting said path to the fixed value is applied and the delay time in said measurement path measured with the signal applied to said path that influences crosstalk to said measurement path.

7. A method for generating patterns for testing a semiconductor integrated circuit having a scan path circuit by a computer, the method comprising the steps of:
generating information on a path (termed an aggressor path) that influences crosstalk to a measurement path of a combinational circuit for measuring a delay, on the basis of layout information on said semiconductor integrated circuit, the combinational circuit being disposed between a plurality of registers, each of which comprises one or plural flip-flops constituting a scan path; and
generating a pattern for causing a flip-flop associated with said measurement path to output a signal supplied to said measurement path for measuring a delay, and generating a pattern for causing a flip-flop associated with said aggressor path to output a signal supplied to said aggressor path for checking on influence of crosstalk to said measurement path.

8. A method for generating patterns for testing a semiconductor integrated circuit having a scan path circuit by a computer, the method comprising the steps of:
(a) extracting one or plural adjacent paths on the basis of layout information on said semiconductor integrated circuit to extract information on a path that influences crosstalk;
(b) generating measurement path information on a measurement path in a combinational circuit for measuring a delay, the combinational circuit being disposed between a plurality of registers, each of which comprises one or plural flip-flops constituting a scan path, said measurement path information including a combination of nodes constituting said measurement path and transition information of a signal at respective nodes, and generating aggressor path information comprising node information on a path (termed an aggressor path) that influences crosstalk to said measurement path, by referring to said extracted information on crosstalk; and
(c) generating a pattern for outputting a signal that should be set for allowing a signal for measuring a delay supplied to said measurement path to propagate through said measurement path, said pattern being outputted from an associated flip-flop of a register on an input side of said measurement path, and generating a pattern for outputting a signal that should be set so as to be supplied to said aggressor path for influencing crosstalk to said measurement path for propagation through said aggressor path from an associated flip-flop of a register on an input side of said aggressor path, on the basis of circuit information on said semiconductor integrated circuit, said measurement path information, and said aggressor path information.

9. An apparatus for generating patterns for testing a semiconductor integrated circuit having a scan path circuit, the apparatus comprising:
means for generating information on a path (termed an aggressor path) that influences crosstalk to a measurement path of a combinational circuit for measuring a delay, on the basis of layout information on said semiconductor integrated circuit, the combinational circuit being disposed between a plurality of registers, each of which comprises one or plural flip-flops constituting a scan path; and
means for generating a pattern for causing a flip-flop associated with said measurement path to output a signal supplied to said measurement path for measuring a delay, and generating a pattern for causing a flip-flop associated with said aggressor path to output a signal supplied to said aggressor path for checking on influence of crosstalk to said measurement path.

10. An apparatus for generating patterns for testing a semiconductor integrated circuit having a scan pass circuit, the apparatus comprising:
means for extracting adjacent wiring paths on the basis of layout information on said semiconductor integrated circuit to extract information on a path that influences crosstalk;
means for generating measurement path information on a measurement path of a combinational circuit for measuring a delay, the combinational circuit being disposed between a plurality of registers, each of which comprises one or plural flip-flops constituting a scan path, said measurement path information comprising a combination of nodes constituting said measurement path and transition information of a signal at the nodes, and generating aggressor path information comprising node information on the path that influences crosstalk to said measurement path, by referring to said extracted information on crosstalk; and
means for generating a pattern for outputting a signal that should be set for allowing a signal for measuring the delay to propagate through said measurement path, said pattern being outputted from an associated flip-flop of a register on an input side of said measurement path, and generating a pattern for outputting a signal that should be set so as to be supplied to said aggressor path for influencing crosstalk to said measurement path for propagation through said aggressor path from an associated flip-flop of a register on an input side of said aggressor path, on the basis of circuit information on said semiconductor integrated circuit, said measurement path information, and said aggressor path information.

11. A method for testing a semiconductor integrated circuit having a scan path circuit as a device under test with an LSI tester, the method comprising:
(a) a first step for setting said semiconductor integrated circuit to a scan mode to serially supply from a scan-in terminal on said semiconductor integrated circuit initialization patterns,
said initialization patterns including:
a pattern for initializing a flip-flop with an output terminal thereof connected to an input terminal of a measurement path in a combinational circuit for measuring a delay and a path (termed an aggressor path) that influences crosstalk to said measurement path, respectively, the combinational circuit having an input terminal thereof connected to an output terminal of a register comprised of one or plural flip-flops constituting a scan path and an output terminal thereof connected to an input terminal of a register comprised of one or plural flip-flops constituting said scan path;
a pattern for setting one or plural flip-flops that should be set so as to influence statuses of the input terminals of said measurement path and said aggressor path to undergo transitions from the initial states to predetermined states, the one or plural flip-flops being connected through a combinational circuit to data input terminals of said flip-flops; and
a pattern for setting one or plural flip-flops that should be set so as to cause signals to propagate through said measurement path and said aggressor path to predetermined states;
(b) a second step for setting said semiconductor integrated circuit from the scan mode to a normal mode to cause the flip-flop that outputs the signal to the input terminal of said measurement path to latch a signal applied to a data input end thereof on a first clock, thereby causing the output signal thereof to be changed from the initial state and also to cause the flip-flop that outputs the signal to the input end of said aggressor path to latch a signal applied to a data input terminal thereof on the first clock, thereby causing the output signal thereof to be changed from the initial state, and then causing the flip-flop that receives at a data input terminal thereof the signal at an output end of said measurement path to receive the outputted signal at the data input terminal thereof on a second clock;
(c) a third step for setting said semiconductor integrated circuit to the scan mode again to read out values of the flip-flops that constitutes the scan path from a scan-out terminal arranged on said semiconductor integrated circuit, and then comparing the value of the flip-flop that receives the outputted signal outputted from the output end of said measurement path at the data terminal thereof with an expected value; and
(d) decreasing a clock period by a predetermined period of time if a result of said comparison is a pass, and increasing the clock period by a predetermined period of time if the result of said comparison is a fail, executing the first, second, and third steps, and then determining the clock period at a transition time when the result of said comparison has changed from the pass to the fail, or from the fail to the pass, to be the delay time in said measurement path under the influence of crosstalk.

12. A method for testing a semiconductor integrated circuit having a scan path circuit as a device under test with an LSI tester as a testing device, the method comprising:
(a) a first step for setting said semiconductor integrated circuit to a scan mode to serially supply from a scan-in terminal on said semiconductor integrated circuit initialization patterns,
said initialization patterns including:
a pattern for initializing a flip-flop with an output terminal thereof connected to an input terminal of a measurement path of a combinational circuit for measuring a delay, said combinational circuit having an input terminal thereof connected to an output terminal of a register comprising one or plural flip-flops constituting a scan path and an output terminal thereof connected to an input terminal of a register comprising one or plural flip-flops constituting said scan path;
a pattern for initializing a flip-flop connected to a path that influences crosstalk to a clock signal path for supplying a clock to a flip-flop connected to said measurement path, said path that influences crosstalk being hereinafter referred to as an aggressor path;
a pattern for setting one or plural flip-flops that should be set so as to cause a status of the input terminal of said measurement path to be changed from the initial state, to predetermined states, the one or plural flip-flops being connected to respective data terminals of said flip-flops through a combinational circuit;
a pattern for setting one or plural flip-flops that should be set so as to cause an input terminal of said aggressor path to be changed from the initial state to a state in phase or in opposite phase with the clock, to predetermined states; and
patterns for setting one or plural flip-flops that should be set so as to cause signals to propagate through said measurement path and said aggressor path to predetermined states;
(b) a second step for setting said semiconductor integrated circuit from the scan mode to a normal mode to cause the flip-flop that outputs the signal to the input end of said measurement path to latch a signal applied to a data input terminal thereof on a first clock, thereby causing the output signal to be changed from the initial state and also to cause the flip-flop that outputs the signal to the input terminal of said aggressor path to latch a signal applied to a data input terminal thereof on the first clock, thereby causing the output signal to be changed from the initial state, and then causing the flip-flop that receives from a data input terminal thereof the signal at an output end of said measurement path to receive the output signal at the data input terminal thereof on a second clock;
(c) a third step for setting said semiconductor integrated circuit to the scan mode again to read out values of the flip-flops that constitutes the scan path from a scan-out terminal on said semiconductor integrated circuit, and then comparing the value of the flip-flop that receives the outputted signal outputted from the output terminal of said measurement path at the data terminal thereof with an expected value; and
(d) a fourth step for decreasing a clock period by a predetermined period of time if a result of said comparison is a pass, and increasing the clock period by a predetermined period of time if the result of said comparison is a fail, executing the first, second, and third steps, and then determining the clock period at a transition time when the result of said comparison has changed from the pass to the fail, or from the fail to the pass, to be the delay time in said measurement path with an effect of crosstalk.

13. The method according to claim 11, further comprising the steps of:
supplying a signal for setting said path that influences crosstalk to said measurement path to a fixed value from the flip-flop associated with the path so as to measure a delay time in said measurement path; and
evaluating the influence of crosstalk on the basis of a difference between the delay time in said measurement path measured after the signal for setting said path to the fixed value is supplied and the delay time in said measurement path measured with the signal supplied to said path that influences crosstalk to said measurement path.

14. A computer program product for causing a computer to execute processes for generating patterns for testing a semiconductor circuit having a scan path circuit, the program product comprising the processes of:
(a) generating information on a path (termed an aggressor path) that influences crosstalk to a measurement path of a combinational circuit for measuring a delay, on the basis of layout information on said semiconductor integrated circuit, the combinational circuit being disposed between a plurality of registers, each of which comprises one or plural flip-flops constituting a scan path; and
(b) generating a pattern for causing a flip-flop associated with said measurement path to output a signal supplied to said measurement path -for measuring a delay, and generating a pattern for causing a flip-flop associated with said aggressor path to output a signal supplied to said aggressor path for checking on influence of crosstalk to said measurement path.

15. A computer program product for causing a computer to execute processes for generating patterns for testing a semiconductor circuit having a scan path circuit, the program product comprising the processes of:
(a) extracting adjacent one or plural paths on the basis of layout information on said semiconductor integrated circuit to extract information on a path that influences crosstalk;
(b) generating measurement path information on a measurement path of a combinational circuit for measuring a delay, the combinational circuit being disposed between a plurality of registers, each of which comprises one or plural flip-flops constituting a scan path, said measurement path information comprising a combination of nodes constituting said measurement path and transition information of a signal at the nodes, and generating path information comprising node information on the path (termed an aggressor path) that influences crosstalk to said measurement path, by referring to said extracted information on crosstalk; and
(c) generating a pattern for outputting a signal that should be set for allowing a signal for measuring a delay to propagate through said measurement path, said pattern being outputted from an associated flip-flop of a register on an input side of said measurement path, and generating a pattern for outputting a signal that should be set so as to be supplied to said aggressor path for influencing crosstalk to said measurement path and for propagation through said aggressor path from an associated flip-flop of a register on an input side of said aggressor path, on the basis of circuit information on said semiconductor integrated circuit, said measurement path information, and said aggressor path information.

16. A computer program product for causing a computer to execute processes for generating patterns for testing a semiconductor circuit having a scan path circuit, the program product comprising the processes of:
(a) extracting adjacent one or plural paths on the basis of layout information on said semiconductor integrated circuit to extract information on a path that influences crosstalk;
(b) generating measurement path information on a measurement path of a combinational circuit for measuring a delay, the combinational circuit being disposed between a plurality of registers, each of which comprises one or plural flip-flops constituting a scan path, said measurement path information comprising a combination of nodes constituting said measurement path and transition information of a signal at the nodes, and generating path information comprising node information on a path (termed an aggressor path) that influences crosstalk to a clock signal path for supplying a clock to a flip-flop associated with said measurement path, if said path exists, said path that influences crosstalk, by referring to said extracted information on crosstalk; and
(c) automatically generating a pattern for outputting the signal that should be set for allowing a signal for measuring the delay to propagate through said measurement path from an associated flip-flop of a register on an input side of said measurement path, and generating a pattern for outputting a signal that should be set so as to be supplied to said aggressor path for influencing crosstalk to said measurement path for propagation through said aggressor path from an associated flip-flop of a register on an input side of said aggressor path, on the basis of circuit information on said semiconductor integrated circuit, said measurement path information and said clock signal path information, and said aggressor path information.

17. The method according to claim 5, further comprising the steps of:
supplying a signal for setting said path that influences crosstalk to said measurement path to a fixed value from the flip-flop associated with said path so as to measure the delay in said measurement path; and
evaluating an effect of crosstalk on the basis of a difference between the delay in said measurement path measured after the signal for setting said path to the fixed value is applied and the delay in said measurement path measured with the signal applied to said path that influences crosstalk to said measurement path.

18. The method according to claim 12, further comprising the steps of:
supplying a signal for setting said path that influences crosstalk to said measurement path to a fixed value from the flip-flop associated with the path so as to measure the delay in said measurement path; and
evaluating the influence of crosstalk on the basis of a difference between the delay in said measurement path measured after the signal for setting said path to the fixed value is supplied and the delay in said measurement path measured with the signal supplied to said path that influences crosstalk to said measurement path.
